(19) United States
(12) Patent Application Publication
(10) Pub. No.: US 2022/0123197 A1
(43) Pub. Date: Apr. 21, 2022

(54) METHOD FOR MANUFACTURING PIEZOELECTRIC TEXTILE ENERGY HARVESTER AND SENSOR

(71) Applicant: V-TRION GMBH TEXTILE RESEARCH, Hohenems (AT)

(72) Inventors: Ishtia Zahir HOSSAIN, HOHENEMS (AT); Khondaker Gaffar HOSSAIN, Hohenems (AT); Gunter GRABHER, Lustenau (AT)

(21) Appl. No.: 17/424,735

(22) PCT Filed: Feb. 4, 2020
(86) PCT No.: PCT/EP2020/052750

§ 371 Date: Jul. 21, 2021

(30) Foreign Application Priority Data
Feb. 4, 2019 (AT) A 60023/2019

(51) Int. Cl. H01L 41/08; H02N 2/18; H01L 41/113; H01L 41/193; H01L 41/253; H01L 41/312

(52) U.S. Cl. CPC H01L 41/082; H02N 2/181; H02N 2/186; H01L 41/312; H01L 41/193; H01L 41/253; H01L 41/1132

(57) ABSTRACT

Energy harvesting device comprising: a first layer (1) of electrically conductive textile fabric material; a second layer (2) of electrically conductive textile fabric material; a layer of piezoelectric polymer film (3) arranged between the first (1) and the second (2) electrically conductive textile layers; wherein the piezoelectric polymer film layer (3) is laminated between the first (1) and second (2) electrically conductive textile layer.

The present invention relates to a piezoelectric textile composite material for harvesting energy via the conversion of mechanical energy into electrical energy and a process for manufacturing said textile.

### BACKGROUND OF THE INVENTION

Piezoelectricity is exploited in a number of useful applications including energy harvesting. The piezoelectric effect converts mechanical energy into electric current or voltage. It may come from many different sources like human motion, pressure, movement, low-frequency seismic vibrations, or acoustic noise. Piezoelectric energy harvesting is an emerging technology, which has been investigating only since the late 1990s.

There are efforts to integrate piezoelectric material into clothing to convert the motion from the human body into electrical power. For example, these materials can be embedded in shoes to recover “walking energy”.

A way to integrate piezoelectric material into textiles is shown in GB 2 516 987 A. This document discloses an energy-harvesting three-dimensional spacer structure comprising a first and second conductive layer and a piezoelectric spacer material interconnecting the conductive layers in the form of piezoelectric spacer yarns. The piezoelectric spacer material may comprise a polymer (such as PVFD) and is knitted between the conductive layers. The piezoelectric material also may be polarized and the conductive layers have to be either knitted or woven.

### SHORT DESCRIPTION OF THE INVENTION

The disadvantages of GB 2 516 987 A are on the one hand that it is difficult to produce the energy-harvesting spacer structure due to the knitting or weaving of the material and on the other hand that the contact surface of the piezoelectric material with the conductive material is very small, as they are just knitted together.

Hence, the object of the present invention is to improve the energy-harvesting device described in GB 2 516 987 A in terms of production simplicity and in terms of the properties of the energy-harvester.

A solution to the above mentioned problem is provided by a piezoelectric textile composite material for harvesting energy, which comprises a first layer of electrically conductive textile fabric material, a second layer of electrically conductive textile fabric material and a layer of piezoelectric polymer film comprised between the first and the second electrically conductive textile layers. The piezoelectric polymer film layer is plasma treated and laminated between the first and second electrically conductive textile layer.

In this context, the piezoelectric effect induces an electric current in the textile due to the influence of mechanical stress.

More precisely, a low-pressure plasma treatment for the piezoelectric polymer film layer allows a surface activation to enhance adhesion between the first and second electrically conductive layers and the polymer film layer.

Furthermore, a lamination process allows interconnecting the piezoelectric polymer film layer with the first and second conductive textile layers.

The plasma activation and the lamination process allow for a very good connection of the conductive layers with the piezoelectric polymer film layer. Thus, more charges can be transferred, which makes the energy harvester more effective.

In a preferred embodiment the layer of piezoelectric polymer film of the textile based piezoelectric energy harvesting device and sensor is polarized.

The first and second electrically conductive textile layers comprise any 2D or 3D fabric made of natural or synthetic and woven, knitted, embroidered or non-woven material. Moreover, these layers are preferably coated with conductive material. The coating may be selected from metallic and/or carbon and/or polymeric conductive material, preferably silver, carbon or poly(3,4-ethylenedioxythiophene) polystyrene sulfonate (PEDOT:PSS).

The layer of piezoelectric polymer film comprises material with piezoelectric properties. Preferably, this material comprises a polarized polyvinylidenefluoride (PVDF) film and/or a modified polarized PVDF film. Furthermore, also the piezoelectric layer may be coated with conductive layers based on metal or conductive polymer preferably with carbon, silver and poly(3,4-ethylenedioxythiophene) polystyrene sulfonate.

The textile based piezoelectric energy harvester according to the invention is very thin and flexible. Thus, the textile is comfortable to wear and can be easily integrated within human wearables or any movable, rotating or vibrating device to detect their vibration or movement and simultaneously generate energy from these motions.

The invention also relates to a method for manufacturing a textile based piezoelectric energy harvesting device and sensor. This method comprises a lamination process of the piezoelectric polymer film layer between the first and second electrically conductive textile layers. The temperature in the lamination process is in the range of 70 to 190° C., preferably 80 to 170° C., wherein the pressure in the lamination process is 1 to 40 N, preferably 35 to 40 N and the energy input is from 0.5 to 3 kW, preferably from 1 to 2 kW.

The piezoelectric polymer film layer is preferably polarized before the lamination process.

Furthermore, the piezoelectric polymer film layer is treated with a low pressure plasma before the lamination process. More precisely, it is activated with oxygen containing functional groups using a mixture of argon and molecular oxygen at a ratio of 1 to 4, wherein the pressure of the plasma is preferably between 0.1 and 0.5 mbar, wherein the exposure time is preferably between 30 and 600 s and the energy input is from 0.5 to 3 kW, preferably from 1 to 2 kW.

The method for producing the energy harvesting device comprises four main steps as summarized below.

In step 1 the conductive textiles, namely the first and second electrically conductive layers, are prepared. For this purpose, either the textile or nonwoven is coated with the conductive material or a knitted or embroidery structure is produced containing a conductive thread.

The next step, step 2, of the method is the activation of the piezoelectric polymer film layer with plasma, as explained above. This is mainly done to increase the adhesion for the next step.

In step 3, the energy harvesting device is completed by laminating the polymer film layer between the first and second layer as described above. Preferably, an outer protective PU layer is used for the lamination.

In the last step, step 4 several energy conversion techniques may be developed. The device has to be produced in a way such that the mechanical energy in form of movement etc. is converted into electrical energy. For the purpose of converting these AC voltages then into DC voltages a rectifying circuit is integrated in the device. In this last step of the production of the inventive device also means for storing the energy may be provided. Moreover, the device may be configured in such a way that it can be used as a sensor.

Summarizing, the inventive textile based piezoelectric energy-harvesting device comprises embroidery or knitted textile structures as top and bottom electrodes. These conductive layers provide a huge surface area that is in contact with the piezoelectric polymer film surface by vibrations, movement or pressure. The large surface allows generating power easily.

Another advantage of the inventive energy harvester is that it is washable and that it allows for a protection against moisture. Preferably, the outer shell of the device is a washable

Polyurethane layer. Thus, the device is functioning in any humid environment.

### DETAILED DESCRIPTION AND PREFERRED EMBODIMENTS

The textile based piezoelectric composite material of the present invention acts as an electrical energy-generating device by means of mechanical action such as movement, deformation, vibration or pressure. When such an external energy is applied to the energy harvesting device the piezoelectric film generates AC voltages, which are converted to DC voltages by a rectifying circuit. This circuit is integrated in the device. The generated DC voltages may then be read out by an oscilloscope.

The foregoing and other objects, features and advantages of the invention will become more apparent from the following detailed description, which proceeds with reference to the accompanying figures.

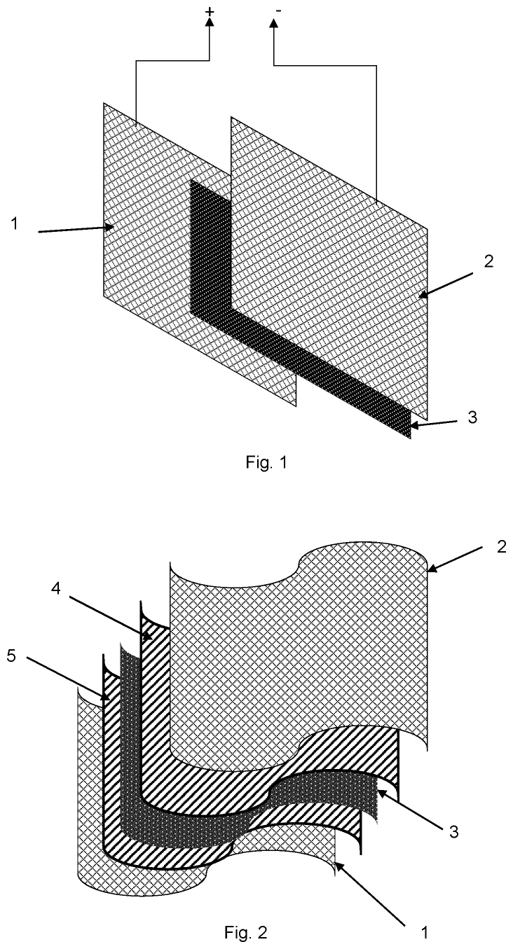

FIG. 1 shows the three layers of the inventive composite piezoelectric textile with an oscilloscope measuring the generated voltages.

FIG. 2 shows the layers of the inventive piezoelectric textile including conductive coatings on both sides of the piezoelectric layer.

FIG. 1 depicts the textile based piezoelectric energy harvesting device and sensor comprises a first layer 1 of electrically conductive textile fabric material, a second layer 2 of electrically conductive textile fabric material and a layer of piezoelectric polymer film 3 laminated between the first 1 and the second 2 electrically conductive textile layers.

The piezoelectric polymer film layer 3 may have conductive layers 4, 5 at each side as shown in FIG. 2. After coating the piezoelectric polymer film layer 3 with the conductive layers 4, 5 it may be laminated between the first 1 and second 2 electrically conductive textile layers.

An important advantage of the inventive energy harvester is that any conductive material can be used for the conductive layers 4, 5. The textile material may be a weaved, knitted, embroidery or nonwoven structure. One can use these various structures due to the fact that the piezoelectric polymer film layer 3 is laminated between the conductive layers 4, 5. Furthermore, the lamination step simplifies the production of the energy harvester.

In order to enhance adhesion of the layers in the lamination process, the surface of the layer of piezoelectric polymer film 3 is activated beforehand. The surface activation is done by a low-pressure plasma treatment.

A big advantage of the so produced energy harvester is that is washable and very durable. Thus, it can be easily integrated into clothing to generate energy from human movement. This is especially effective if it is integrated into sports clothing. Moreover, these energy generating textiles may also be used in the context of smart-textiles and textiles used for healthcare, where the generated electrical power may be used immediately.

The inventive self-powering sensors can find their applications also in the transport sector including transport on water, on roads and in the air. In all these applications the important properties of the inventive energy harvester namely flexibility, wearability, washability and comfortability are mandatory. At the same time the energy harvester is very effective in producing energy out of external energy from the ambient environment due to the strong coupling between the piezoelectric polymer film layer and the conductive textile layers. This strong coupling is achieved via the above described plasma treatment of the piezoelectric layer and the subsequent lamination process of the piezoelectric layer with the conductive layers.

1. An energy harvesting device comprising:
a first layer of electrically conductive textile fabric material,
a second layer of electrically conductive textile fabric material,
a layer of piezoelectric polymer film arranged between the first and the second electrically conductive textile layers,
wherein the piezoelectric polymer film layer is laminated between the first and second electrically conductive textile layer.

2. The energy harvesting device according to claim 1, wherein the layer of piezoelectric polymer film is polarized.

3. The energy harvesting device according to claim 1, wherein the piezoelectric polymer film layer is plasma treated.

4. The energy harvesting device according to claim 1, wherein the first and second electrically conductive textile layers comprise any 2D or 3D fabric made of natural fiber or synthetic fiber with a woven, knitted, embroidered or non-woven structure.

5. The energy harvesting device according to claim 4, wherein the natural or synthetic material of the first and second electrically conductive textile layers is coated with conductive material, wherein the coating is selected from metallic and/or carbon and/or polymeric conductive material.

6. The energy harvesting device according to claim 1, wherein the layer of piezoelectric polymer film comprises material with piezoelectric properties, wherein the material comprises a polarized polyvinylidenefluoride (PVDF) film and/or a modified polarized PVDF film.

7. The energy harvesting device according to claim 6, wherein the piezoelectric material of the piezoelectric polymer film layer is coated with conductive layers based on metal or conductive polymer.

8. A sensor comprising an energy harvesting device according to claim 1.

9. A method for manufacturing an energy harvesting device and sensor comprising the steps of
preparing a first electrically conductive textile layer and a second electrically conductive textile layer by either coating a textile or nonwoven with a conductive material or producing a knitted or embroidery structure with a conductive thread,
activating a piezoelectric polymer film layer with plasma,
laminating the piezoelectric polymer film layer between the first and second electrically conductive layers
and integrating a rectifying circuit in the device.

10. The method according to claim 9, wherein the temperature in the lamination process of the piezoelectric polymer film layer between the first and second electrically conductive textile layers is in the range of 70° C. to 190° C., wherein the pressure in the lamination process is in the range of 1 N to 40 N, wherein the energy input is in the range of 0.5 kW to 3 kW.

11. The method according to claim 9, wherein the piezoelectric polymer film layer is polarized before the lamination process.

12. The method according to claim 9, wherein the activation is done with a low pressure plasma, wherein it is activated with oxygen containing functional groups using a mixture of argon and molecular oxygen at a ratio of 1 to 4.

13. The energy harvesting device according to claim 5, wherein the coating is selected from silver, carbon, or poly(3,4-ethylenedioxythiophene) polystyrene sulfonate (PEDOT:PSS).

14. The energy harvesting device according to claim 7, wherein the metal or conductive polymer includes carbon, silver, or poly(3,4-ethylenedioxythiophene) polystyrene sulfonate.

15. The method according to claim 9, wherein the temperature in the lamination process of the piezoelectric polymer film layer between the first and second electrically conductive textile layers is in the range of 80° C. to 170° C., wherein the pressure in the lamination process is in the range of 30 N to 40 N, wherein the energy input is in the range of 1 kW to 2 kW.

16. The method according to claim 12, wherein the pressure of the plasma is in the range of 0.1 mbar to 0.5 mbar.

17. The method according to claim 12, wherein the exposure time is in the range of 30 s to 600 s.
